(19) United States
(12) Patent Application Publication
(10) Pub. No.: US 2026/0276670 A1
(43) Pub. Date: Sep. 17, 2026

(54) MEMS SENSOR COMPONENT, MEMS SENSOR DEVICE, AND METHOD FOR OPERATING THE MEMS SENSOR DEVICE

(71) Applicant: Robert Bosch GmbH, Stuttgart (DE)

(72) Inventor: Volkmar Senz, Metzingen (DE)

(21) Appl. No.: 19/560,259

(22) Filed: Mar. 9, 2026

(30) Foreign Application Priority Data
Mar. 12, 2025 (DE) 10 2025 109 497.7

(51) Int. Cl. G01P 15/125

(52) U.S. Cl. CPC G01P 15/125

(57) ABSTRACT

A MEMS sensor component. The MEMS sensor component include a support structure, a first membrane and a second membrane which are anchored to the support structure and connected to one another by an end wall, a cavity which is bordered by the support structure, the first membrane, the second membrane, and the end wall, a sound measuring apparatus arranged in the cavity for detecting a sound signal acting on the first membrane and/or the second membrane, and an acceleration measuring apparatus arranged in the cavity for detecting an acceleration force acting on the MEMS sensor component. A MEMS sensor device and a method for operating the MEMS sensor device are also described.

### CROSS REFERENCE

The present application claims the benefit under 35 U.S.C. § 119 of Germany Patent Application No. DE 10 2025 109 497.7 filed on Mar. 12, 2025, which is expressly incorporated herein by reference in its entirety.

### FIELD

The present disclosure relates to a MEMS sensor component. The present disclosure further relates to a MEMS sensor device with such a MEMS sensor component and a method for operating the MEMS sensor device.

### BACKGROUND INFORMATION

Certain MEMS sensor components are described in the related art. The abbreviation MEMS stands for microelectromechanical systems, which, through microstructural properties and suitable production processes, make it possible to miniaturize electromechanical functional components such as actuators and sensors.

PCT Patent Application No. WO 2016/057007 A1 describes a MEMS sensor component in which at least two different sensor types are arranged on a common substrate. For example, a pressure sensor, an acceleration sensor and a microphone can be arranged on the substrate.

### SUMMARY

In accordance certain features of the present disclosure, a MEMS sensor component is provided. According to an example embodiment, the MEMS sensor component includes:
a support structure,
a first membrane and a second membrane which are anchored to the support structure and connected to one another by an end wall,
a cavity that is bordered by the support structure, the first membrane, the second membrane and the end wall,
a sound measuring apparatus arranged in the cavity for detecting a sound signal acting on the first membrane and/or the second membrane, and
an acceleration measuring apparatus arranged in the cavity for detecting an acceleration force acting on the MEMS sensor component.

Stated simply, it is provided to arrange a sound measuring apparatus and an acceleration measuring apparatus in a common cavity of a double membrane system, whereby several sensor variables can be detected with the compact design of the MEMS sensor component. This provides a versatile combination sensor component in which an additional acceleration sensor is integrated directly into the double membrane system so that in addition to a sound measurement function, an acceleration measurement function is provided, and a possibly provided acceleration sensor outside the double membrane system can be omitted. Advantageously, a spatial region in the cavity can be used for the arrangement of the acceleration measuring apparatus that is of little relevance for sound measurement so that the overall efficiency of the MEMS sensor component can be increased by suitable spatial distribution of the sound measuring apparatus and the acceleration measuring apparatus. By arranging the sound measuring apparatus and the acceleration measuring apparatus in the cavity in which in particular an internal pressure reduced compared to atmospheric pressure can be set, the measuring apparatuses are hermetically and electrostatically shielded from the environment. This provides a robust MEMS sensor component with high measurement accuracy.

A MEMS sensor component can be a sensor component with mechanical and electrical microstructures produced using semiconductor technology and, due to its microstructural design, can be suitable for implementation as a system-on-chip (SoC). The MEMS sensor component can be configured to detect physical sensor variables such as static and dynamic pressures as well as accelerations.

According to example embodiments, the support structure can be a mechanical carrier structure to which the membranes as well as components of the sound measuring apparatus and the acceleration measuring apparatus can be fastened. The mechanical carrier structure can be formed, for example, by a recess in a substrate, for example in a silicon wafer, wherein a substrate surface surrounding the recess represents a fastening surface for the mentioned structures. Such a recess can, for example, have a circular or square cross section, but in principle any other geometric cross-sectional shape as well. The recess can also form a pressure access for the MEMS sensor component.

The first membrane and the second membrane can be considered as movable microstructures of the MEMS sensor component. They can be designed flat and have a width and length several times greater than the thickness. The first and the second membranes interact with the environment of the MEMS sensor component and can be deflected, at least in portions, by a static pressure signal and a dynamic sound signal, for example. Various design parameters such as the material, geometric shape, dimensions and the connection of the membranes to the support structure, can influence their sensitivity. The first membrane and the second membrane are suspended horizontally on the support structure and can, for example, run substantially parallel to a substrate surface of a substrate forming the support structure in a resting state. The first membrane and the second membrane are at fastened a distance from one another to the support structure and can substantially run parallel to one another in a resting state.

The end wall can be viewed as a connecting element or a frame structure that runs transversely to the first and second membranes and connects them at their ends. The end wall can be arranged at a distance from the support structure. It can substantially run parallel to a fastening surface of the membranes on the support structure. A ventilation opening, in particular a central ventilation opening, in the MEMS sensor component can be limited by means of a surrounding end wall.

The cavity can be viewed as an enclosed space between the support structure, the first and second membranes, and the end wall. The cavity forms a measuring chamber in which electromechanical microstructures are arranged for measurement signal generation. In particular, the internal pressure in the cavity is reduced compared to atmospheric pressure, which allows a noise reduction to be achieved with a resulting increase in the signal-to-noise ratio.

The sound measuring apparatus, together with the first and second membranes, can be considered a microphone. The sound measuring apparatus is an electromechanical transducer apparatus for detecting a mechanical sound signal acting on the membranes and serves to generate an electrical measurement signal representative of the sound signal. The acceleration measuring apparatus can be viewed as an electromechanical transducer apparatus for detecting a mechanical acceleration signal at the MEMS sensor component. By means of a seismic mass arranged in the cavity, the acceleration measuring apparatus can generate an electrical measurement signal representative of the acceleration. In particular, a plurality of acceleration measuring apparatuses can be arranged distributed in the MEMS sensor component to increase measurement accuracy. The acceleration measuring apparatus can be spaced from the sound measuring apparatus by a separating gap. It is also possible that at least individual components of the acceleration measuring apparatus and the sound measuring apparatus mechanically merge into one another, for example in the form of a jointly formed stationary counter electrode, as will be explained in more detail below. The sound measuring apparatus can be spaced from the end wall by a separating gap.

In accordance with one example embodiment, the sound measuring apparatus can be designed as a capacitive sound measuring apparatus. Alternatively or additionally, the acceleration measuring apparatus can be designed as a capacitive and/or piezoelectric acceleration measuring apparatus. This allows for a simple and compact design of the MEMS sensor component. Furthermore, with a capacitive measuring apparatus, a reliable and accurate measuring principle can be used for detecting deflections of the first and second membranes and/or a seismic mass of the acceleration measuring apparatus. In this context, capacitive measuring apparatuses can be understood as sensor components whose generation of an electrical measurement signal is based on the detection of changes in distance between an electrode and a counter electrode caused by mechanical influences. A piezoelectric acceleration measuring apparatus can be designed even smaller than a capacitive measuring apparatus since no dual structure consisting of an electrode and counter electrode is required. The additional installation space gained by eliminating the counter electrode can be advantageously used to increase the seismic mass. For example, a seismic mass of the acceleration measuring apparatus can be fastened to the support structure via a spring arm, and a piezoelectric element can be arranged in the spring arm. With a piezoelectric element, a mechanical stress effect in the spring arm can be converted into an electrical signal upon a deflection of the seismic mass. The acceleration measuring apparatus can also have a piezoelectric sensor structure in addition to a capacitive sensor structure.

In accordance with one example embodiment, starting from the fastening of the acceleration measuring apparatus to the support structure viewed in the direction of the end wall, the acceleration measuring apparatus and the sound measuring apparatus can follow one another. This allows for efficient use of installation space without significant impairment of the sound measurement function. Expressed differently, in the portion or in the portions of the MEMS sensor component in which an acceleration measuring apparatus is arranged, said apparatus is located in an outer region between the support structure and the sound measuring apparatus. In such an outer region near the connection of the membranes to the support structure, the deflection of the membranes due to external influences is lower because of the mechanical fastening so that the outer region is of little relevance in terms of sound measurement. For example, with a capacitive measuring principle, a significantly smaller change in capacitance can be measured in the outer region due to the smaller membrane deflection than in a region of the membrane under consideration further away from the support structure. The sound measuring apparatus also fastened to the support structure can, for example, be anchored laterally to the acceleration measuring apparatus on the support structure. A significant portion of the acceleration measuring apparatus can be located closer to the support structure than to the end wall. A significant portion of the sound measuring apparatus can be arranged closer to the end wall than to the support structure. For example, the acceleration measuring apparatus can be arranged along a distance between the support structure and the end wall in a first third of the distance starting from the support structure, and the sound measuring apparatus can be arranged in the further two thirds of the distance in the direction of the end wall.

In accordance with one example embodiment, the acceleration measuring apparatus can have a stationary acceleration measuring electrode and a mass electrode movable relative to the stationary acceleration measuring electrode. This allows a simple and compactly designed acceleration measuring apparatus with a capacitive measuring principle to be provided. A change in capacitance between the mass electrode and the stationary acceleration measuring electrode can be representative of an acceleration acting on the MEMS sensor component. The mass electrode can be arranged between the stationary acceleration measuring electrode and the first or second membrane. In accordance with one possible design, the acceleration measuring apparatus can have at least two mass electrodes arranged next to one another in a horizontal plane. The acceleration measuring apparatus can form a uniaxial acceleration sensor, in particular a z-acceleration sensor. The stationary acceleration measuring electrode can be considered a rigid counter electrode to the mass electrode. The stationary acceleration measuring electrode can be anchored to one side the support structure and protrude towards the end wall. The mass electrode can form a seismic mass of the acceleration measuring apparatus, which can be deflected vertically, i.e., substantially transversely to a main extension of the first and second membranes.

In accordance with one example embodiment, the mass electrode can be fastened to the support structure by means of a spring arm arranged between the stationary acceleration measuring electrode and the first membrane or the second membrane. With such a fastening of the mass electrode via a spring arm, it is suspended in a space-saving and movable manner and can be deflected relative to the acceleration measuring electrode. The spring arm can extend substantially horizontally between the acceleration measuring electrode and the first or second membrane. The spring arm can be integrally formed with the mass electrode. The spring arm can have a smaller height extension between the stationary acceleration measuring electrode and the first or second membrane than the mass electrode so that the spring arm has a lower bending stiffness than the mass electrode, and sufficient deflection of the mass electrode is therefore ensured. Since the acceleration measuring apparatus can be arranged close to the support structure, the spring arm can be designed to be comparatively short and with a small height extension in order to achieve the desired mobility of the mass electrode. In contrast, the mass electrode can have a greater height extension than the spring arm in order to efficiently fill a gap between the stationary acceleration measuring electrode and the first or second membrane and to achieve an improved deflection of the mass electrode acting as a seismic mass.

In accordance with one example embodiment, the acceleration measuring apparatus can have a first mass electrode arranged between the stationary acceleration measuring electrode and the first membrane and a second mass electrode arranged between the stationary acceleration measuring electrode and the second membrane. This allows optimized installation space use through a favorable distribution of the seismic masses between the membranes and the stationary acceleration measuring electrode. Furthermore, a differential evaluation of the measurement signals generated by the deflection of the first and second mass electrodes can be implemented.

In accordance with one example embodiment, the first mass electrode and the second mass electrode can be mechanically connected to one another by a connecting element, wherein the connecting element extends through a recess in the stationary acceleration measuring electrode. By mechanically coupling the first and second mass electrodes, a stronger and more uniform deflection on both sides of the stationary acceleration measuring electrode, as well as improved stability of the mass electrodes of the acceleration measuring apparatus, can be achieved. The connecting element can be designed, in particular, as an elongated connecting web. The connecting element can extend vertically, i.e., substantially transversely to a main extension of the first and second membranes, between the first and second mass electrodes. The connecting element can have electrical insulation between the first and second mass electrodes or be made of an electrically non-conductive material to allow differential evaluation of the measurement signals of the first and second mass electrodes. The electrical insulation can be made of, for example, silicon oxide or silicon nitride. The first and second mass electrodes can be connected to one another, in particular by a plurality of connecting elements, wherein the connecting elements can extend through a common recess or separate recesses in the stationary acceleration measuring electrode.

In accordance with one example embodiment, the first mass electrode can be fastened to the support structure by a first spring arm arranged between the stationary acceleration measuring electrode and the first membrane, and the second mass electrode can be fastened to the support structure by a second spring arm arranged between the stationary acceleration measuring electrode and the second membrane. This allows for a stable suspension of the first and second mass electrodes with good deflectability. The first spring arm and the second spring arm can be designed according to one of the above-described features of the spring arm, for example having a lower height extension than the attached mass electrode. If the first mass electrode and the second mass electrode are mechanically connected to one another by a connecting element, both mass electrodes can be fastened to the support structure via a given spring arm as described above in order to increase the stability of the mass electrodes connected to one another and fastened to the support structure. Alternatively, it is also possible in principle that only the first mass electrode or the second mass electrode is connected to the support structure via a spring arm, and the spring arm serves as a common suspension for both mass electrodes, thereby improving the deflectability of the first and second mass electrodes.

In accordance with one example embodiment, the first membrane and/or the second membrane can have an acceleration measuring portion and a sound measuring portion electrically insulated therefrom, and the acceleration measuring apparatus can have a mass electrode movable relative to the acceleration measuring portion. The first membrane and/or the second membrane can therefore in portions form a quasi-stationary acceleration measuring electrode relative to the mass electrode. This allows the existing first and/or second membrane to be advantageously used as a counter electrode for the movable mass electrode. If, for example, an additional stationary acceleration measuring electrode thereby becomes unnecessary, the saved installation space can be used for an enlargement of the mass electrode. A quasi-stationary acceleration measuring electrode means that the membranes can also be subject to deflection due to external pressure and acceleration effects. However, if the acceleration measuring apparatus is arranged in an outer region of the cavity near the support structure, the deflection of the membranes in their edge region is reduced compared to a membrane center so that the membranes in this region can be considered as nearly stationary counter electrodes. The described embodiment can, for example, be combined with the above-described embodiment, according to which, starting from the fastening of the acceleration measuring apparatus to the support structure viewed in the direction of the end wall, the acceleration measuring apparatus and the sound measuring apparatus follow one another, i.e., the acceleration measuring apparatus is arranged in an outer region. The mass electrode can be placed as close as possible to the support structure, for example arranged at a distance from the support structure of a maximum of 30% or a maximum of 20% of the distance between the support structure and the end wall.

In accordance with one example embodiment, the sound measuring apparatus can have a stationary sound measuring electrode and a signal electrode mechanically coupled to the first membrane or the second membrane, which is movable relative to the stationary sound measuring electrode. With such a signal electrode coupled to the first or second membrane, a sound measurement signal decoupled from the ambient pressure can be provided since the ambient pressure is already absorbed by a corresponding membrane deformation, and a mechanical deflection of the signal electrode primarily represents the actual sound signal. Through the coupling, a deflection of the membrane by the sound signal is mechanically transferred to the signal electrode. In particular, the first and second membranes can each have a coupled signal electrode. The signal electrode can protrude into the cavity towards the sound measuring electrode. The signal electrode can be coupled to the first or second membrane via a plurality of coupling structures spaced-apart from one another. The stationary sound measuring electrode can be anchored to the support structure under tensile stress in order to ensure a straight path, and an accurate measurement signal with the increased stiffness thereby achieved. The signal electrode can have a lower total mass than the mass electrode. This allows acceleration-induced deflections in the sound measurement range to be reduced, which yields a more accurate sound measurement signal, while in the acceleration measurement range, a larger mass in the mass electrode is desirable for precise acceleration detection. The total mass can, for example, refer to the mass of a single signal electrode compared to the mass of a single mass electrode, or to the cumulative mass of signal electrodes attached to the first and second membranes compared to the cumulative mass of a first and second mass electrode, wherein the mass of coupling structures or spring arms is excluded.

In accordance with one example embodiment, the stationary sound measuring electrode and the stationary acceleration measuring electrode can be mechanically and/or electrically separated from one another, thereby facilitating metrological evaluation and reducing parasitic capacitances. The stationary sound measuring electrode and the stationary acceleration measuring electrode can, for example, be mechanically and electrically separated from one another by a separating gap, or mechanically connected to one another and electrically separated from one another by an electrical insulation, for example made of silicon nitride or silicon oxide. The stationary sound measuring electrode and the stationary acceleration measuring electrode can, for example, form a common counter electrode without mechanical separation, which has a sound measurement range and an acceleration measurement range. This forms a very stable counter electrode for the acceleration measuring apparatus and the sound measuring apparatus. Furthermore, the MEMS sensor component is easy to manufacture in this way. The sound measurement range and the acceleration measurement range can be electrically separated from one another by electrical insulation. By mechanically separating the stationary sound measuring electrode and the stationary acceleration measuring electrode, for example by a separating gap, a defined spatial separation of the acceleration measuring apparatus and the sound measuring apparatus with very low parasitic capacitances can be achieved. In principle, embodiments are also possible in which the stationary sound measuring electrode transitions into the stationary acceleration measuring electrode without mechanical or electrical separation, whereby a very simple and robust design of the MEMS sensor component is obtainable.

In accordance with one example embodiment, the stationary sound measuring electrode can have a greater height extension between the first membrane and the second membrane than the stationary acceleration measuring electrode. This achieves a mechanical optimization of the corresponding stationary counter electrode of the sound measuring apparatus and the acceleration measuring apparatus with regard to their position in the sensor component and their function. Accordingly, the stationary acceleration measuring electrode can be designed narrower than the stationary sound measuring electrode since it does not extend as far towards the end wall from its fastening to the supporting wall as the stationary sound measuring electrode so that even with a small height extension, sufficient stiffness and stability of the stationary acceleration measuring electrode is ensured. By means of the narrow design of the stationary sound measuring electrode, additional installation space is provided for the mass electrode which can correspondingly be designed with a larger mass to achieve a greater deflection. A greater installation height of the stationary sound measuring electrode, on the other hand, gives it sufficient stiffness and stability for a straight path even over a longer distance between the support structure and the end wall. In principle, embodiments are also possible in which the stationary sound measuring electrode and the stationary acceleration measuring electrode have the same height extension. This can apply in particular to embodiments in which the stationary sound measuring electrode and the stationary acceleration measuring electrode are not mechanically separated from one another, but merge into one another and form a common stationary counter electrode.

In accordance with one example embodiment, the first membrane or the second membrane and the signal electrode coupled thereto can have electrical potentials separate from one another and form a pressure measuring apparatus. This allows an additional pressure measurement function on the MEMS sensor component to be realized so that a combination sensor component is available with three different sensor variables. By means of the planned potential separation, the additional pressure measurement function can be easily implemented without requiring additional pressure measurement structures on the MEMS sensor component. The signal electrode can therefore, in addition to its function with regard to the sound measuring apparatus, form a counter electrode for the first or second membrane and enable capacitive detection of the ambient pressure. The pressure measuring apparatus can be formed in particular by the first and second membrane and each of the coupled signal electrodes. For potential separation, an electrical insulation can be provided between the membranes and the signal electrodes.

In accordance with one example embodiment, the support structure can form a surrounding fastening surface, the stationary sound measuring electrode and the stationary acceleration measuring electrode can be fastened to different circumferential portions of the fastening surface. This can ensure a sufficient connection of the sound and acceleration measuring electrodes. In particular, a plurality of stationary acceleration measuring electrodes can be connected alternately with a plurality of portions of the fixed sound measuring electrode next to one another to the surrounding support structure. This can yield optimized space utilization with a plurality of acceleration measuring portions and a still sufficient mechanical connection of the stationary sound measuring electrode to the support structure. In this case, a sufficient, for example capacitively effective, measuring surface is always provided for the generation of precise sound and acceleration measurement signals. The support structure can, for example, form a circular, rectangular or square surrounding fastening surface. Other point-symmetric polygon shapes are also possible in this regard. The sound measuring electrode can, for example, be clamped in an X-shape, while the spaces between the X-shape can be filled by acceleration measuring apparatuses. If the stationary sound measuring electrode and the stationary acceleration measuring electrode are mechanically separated from one another, the mechanical separation between the stationary sound measuring electrode and the stationary acceleration measuring electrode can be created in particular by a separating gap of any geometric shape, which can originate and terminate at the support structure and can be repeated along the circumferential portions of the fastening surface. For example, the stationary acceleration measuring electrode can be spaced apart from the stationary sound measuring electrode by an arc-shaped separating gap. A plurality of separating gaps can be symmetrically distributed in the MEMS sensor component. One or more mass electrodes of the acceleration measuring apparatus can, for example, be fitted in a wing-like manner into the acceleration measuring portion mechanically delimited by a separating gap. In an acceleration measuring portion, two mass electrodes spaced apart from one another in a plane can be aligned axially symmetrically to one another. If the stationary sound measuring electrode and the stationary acceleration measuring electrode are mechanically connected to one another but electrically separated, the electrical separation between the stationary sound measuring electrode and the stationary acceleration measuring electrode can be created in particular by an arbitrarily geometrically shaped dielectric element that can originate and terminate at the support structure and can be repeated along the circumferential portions of the fastening surface.

In accordance with one example embodiment, the first membrane and the second membrane can be connected to one another by a mechanical support column that extends through a recess in the stationary sound measuring electrode. This allows the first and second membranes to be stabilized and, for example, prevents the membranes from collapsing into a pressure-reduced interior of the cavity. In particular, the first membrane and the second membrane can be connected to one another by a plurality of support columns, in particular spaced regularly apart from one another. The support column or columns can be arranged in particular in the region of the sound measuring apparatus. Given the support with at least one support column, the first and second membranes are divided into individual deflectable membrane sections. For example, the deflection behavior of the first and second membranes can be specifically adjusted by a column spacing, column shape, column dimensioning and thickness of the first and second membranes so that, among other things, the sensitivity of the MEMS sensor component, in particular the sound measuring apparatus and/or the pressure measuring apparatus, can be influenced by a suitable support column design.

The present disclosure also relates to a MEMS sensor device having a MEMS sensor component according to one of the above-described features and having a signal processing unit which is designed for receiving, applying and/or processing signals of the MEMS sensor component. This provides a versatile, ready-to-use combination sensor with at least two or three sensor variables that can be evaluated either together or independently of one another, and whose measurement signals hardly influence one another. The signal processing unit can be understood as a control and evaluation apparatus for the MEMS sensor component and can, for example, be designed as an application-specific integrated circuit (ASIC). The signal processing unit can, for example, be connected to the electrical conductor tracks of the MEMS sensor component via a wire bond connection. The MEMS sensor device is small and cost-effective to manufacture so that it is suitable for use in smartphones, tablets or other consumer products, for example.

The present disclosure also relates to a method for operating a MEMS sensor device according to one of the features described above, wherein
an acceleration-compensated sound measurement signal from the sound measuring apparatus is provided or processed by the signal processing unit based on an acceleration measurement signal from the acceleration measuring apparatus and/or
an acceleration measurement signal from the acceleration measuring apparatus, a sound measurement signal from the sound measuring apparatus and/or a pressure measurement signal from the pressure measuring apparatus are provided or processed independently of one another by the signal processing unit.

By providing an acceleration-compensated measurement signal, very precise sound measurement signals can be provided, crosstalk effects reduced, and noise reduction achieved to increase the signal-to-noise ratio. Acceleration compensation can be implemented, for example, via a corresponding circuit design on the MEMS sensor component or computationally via the signal processing unit of the MEMS sensor device, wherein computational acceleration compensation is accompanied by increased processing flexibility and allows the use of complex compensation algorithms.

Through independently provided measurement signals from the acceleration measuring apparatus, the sound measuring apparatus and optionally a pressure measuring apparatus of the MEMS sensor device, for example within the framework of a 2-channel or 3-channel output signal structure, the measurement signals can be used for differentiated evaluations and additional functions. For example, the acceleration measurement signal can be used independently of the sound measurement signal for structure-borne sound measurement or for gesture control when using the MEMS sensor device.

The above-described MEMS sensor component, the MEMS sensor device and/or the method for operating the MEMS sensor device can be advantageously used in connection with at least one of the following areas of application: smartphone, tablet: motion detection, context recognition, detection of fall events, motion control. Wearables, hearables, augmented reality, virtual reality: context recognition, calorie counting, in-ear detection, elderly care, indoor navigation, position tracking, head movement tracking. Drones, gaming, toys: altitude stabilization, flight control. Robots: air quality monitoring, blockage detection. Smart home: air quality monitoring, mold detection, air conditioning control, floor detection. Industrial environments: water level detection.

In the context of this application, unless explicitly defined otherwise, the words “a/an” are generally not to be understood as a numeral, but as indefinite articles meaning “at least one.” The present disclosure allows for various embodiments and is explained in more detail below using exemplary embodiments with the figures.

### BRIEF DESCRIPTION OF THE DRAWINGS

FIG. 1 is a section of a MEMS sensor component according to a first example embodiment in a side sectional view along the section line A-A shown in FIG. 2.

FIG. 2 is a section of a MEMS sensor component according to the first example embodiment in a sectional view transverse to the side sectional view shown in FIG. 1.

FIG. 3 is the MEMS sensor component according to the first example embodiment in a side sectional view.

FIG. 4 is a section of a MEMS sensor component according to a second example embodiment in a side sectional view.

FIG. 5 is a section of a MEMS sensor component according to a third example embodiment in a side sectional view.

FIG. 6 is a section of a MEMS sensor component according to a fourth example embodiment in a side sectional view.

FIG. 7 is a section of a MEMS sensor component according to a fifth example embodiment in a side sectional view.

FIG. 8 is a section of a MEMS sensor component according to a sixth example embodiment in a side sectional view.

FIG. 9 is a section of a MEMS sensor component according to a seventh example embodiment in a side sectional view.

FIG. 10 is a schematic diagram of an example MEMS sensor device with a MEMS sensor component;

FIG. 11 a schematic representation of a method for operating a MEMS sensor device according to an exemplary embodiment.

### DETAILED DESCRIPTION OF EXAMPLE EMBODIMENTS

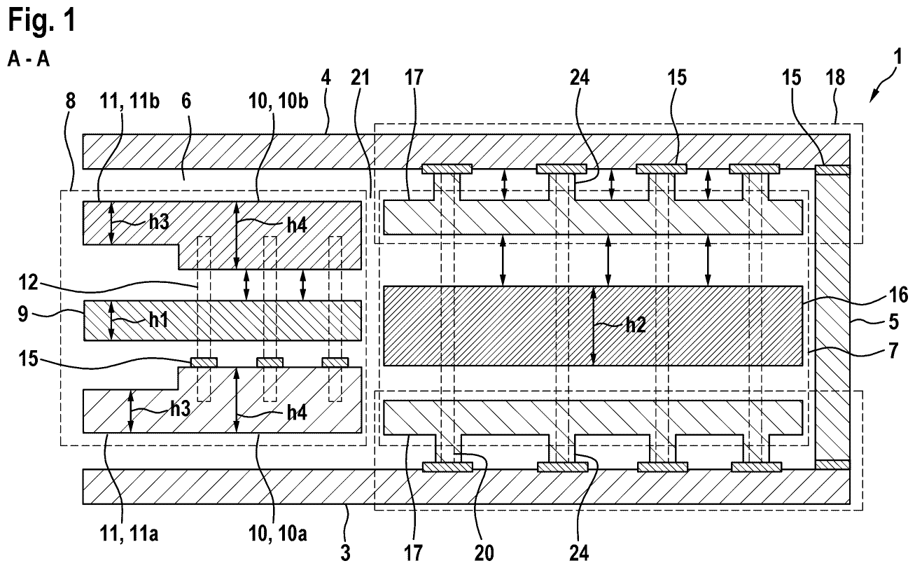

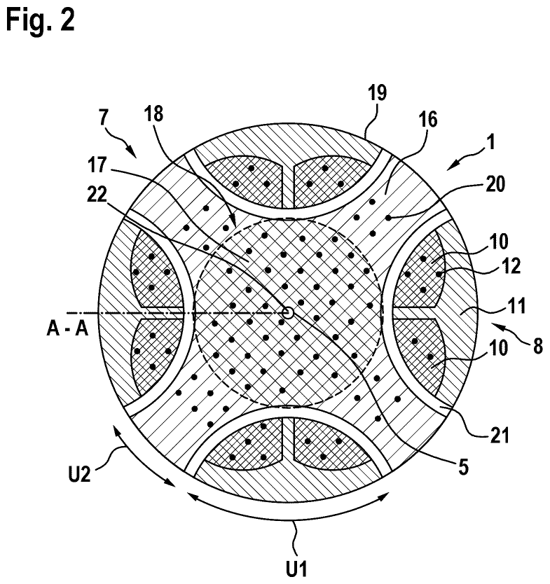

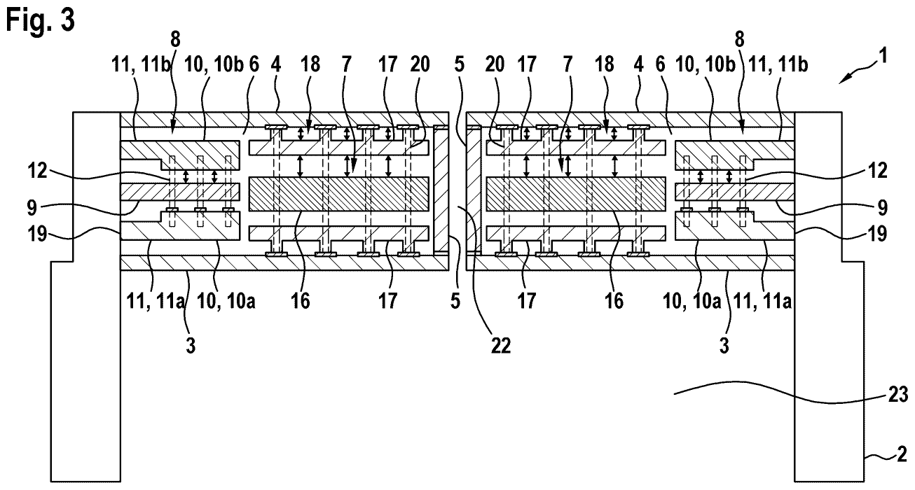

FIG. 1 shows a section of a MEMS sensor component 1 shown in FIG. 3 in a cutaway side view. The MEMS sensor component 1 has a support structure 2, which is hidden in FIGS. 1 and 2 and visible in FIG. 3. FIG. 1 shows that the MEMS sensor component 1 has a first membrane 3 and a second membrane 4 which are electrically separated from one another by an electrical insulation 15. These are anchored to the support structure 2 shown in FIG. 3, suspended in a horizontal orientation and connected to one another by a vertical end wall 5. The support structure 2, the first membrane 3, the second membrane 4 and the end wall 5 border a cavity 6 in which a reduced internal pressure is set. A sound measuring apparatus 7 is arranged in the cavity 6 for detecting a sound signal acting on the first membrane 3 and/or on the second membrane 4. In addition, an acceleration measuring apparatus 8 is arranged in the cavity 6 to detect an acceleration force acting on the MEMS sensor component 1. This provides a versatile and robust MEMS sensor component 1 with high measurement accuracy, with which a plurality of sensor variables can be detected simultaneously. In accordance with the exemplary embodiments shown in FIG. 1 to 6, the sound measuring apparatus 7 is designed as a capacitive sound measuring apparatus 7. The acceleration measuring apparatus 8 illustrated in the exemplary embodiments is also designed as a capacitive acceleration measuring apparatus 8. This enables a simple and compact design of the MEMS sensor component 1.

In FIG. 1, it can be seen that, starting from the fastening of the acceleration measuring apparatus 8 to the support structure 2 viewed in the direction of the end wall 5, the acceleration measuring apparatus 8 and the sound measuring apparatus 7 follow one another, i.e., the acceleration measuring apparatus 8 is arranged in an outer region of the sensor structure with reduced membrane deflection and accordingly reduced relevance for the sound signal measurement. The acceleration measuring apparatus 8 and the sound measuring apparatus 7 are mechanically separated from one another by a separating gap 21 according to the illustrated exemplary embodiment. It can also be found in FIG. 1 that the acceleration measuring apparatus 8 has a stationary acceleration measuring electrode 9 and a mass electrode 10 movable relative to the stationary acceleration measuring electrode 9, wherein the mass electrode 10 is fastened to the support structure 2 via a spring arm 11 formed integrally with the mass electrode 10. Specifically, according to the exemplary embodiment shown in FIG. 1 to 3, a first mass electrode 10a is arranged between the stationary acceleration measuring electrode 9 and the first membrane 3, and a second mass electrode 10b is arranged between the stationary acceleration measuring electrode 9 and the second membrane 4, thereby achieving a favorable spatial distribution of a seismic mass of the acceleration measuring apparatus 8 and enabling differential evaluation.

The first mass electrode 10a and the second mass electrode 10b are mechanically connected to one another by connecting elements 12 as can be seen in FIG. 1 in order to achieve an increased and uniform deflection of the mass electrodes 10a, 10b, wherein the connecting elements 12 extend through recesses not shown in detail in the stationary acceleration measuring electrode 9. The connecting elements 12 enable a potential separation of the mass electrodes 10a, 10b for differential evaluation by means of an electrical insulation 15. The first mass electrode 10a is fastened to the support structure 2 by a first spring arm 11a. The first spring arm 11a extends horizontally between the stationary acceleration measuring electrode 9 and the first membrane 3. The second mass electrode 10b is fastened to the support structure 2 by a second spring arm 11b. The second spring arm 11b extends horizontally between the stationary acceleration measuring electrode 9 and the second membrane 4. By means of the two spring arms 11a, 11b, a stable connection of the mass electrodes 10a, 10b to the support structure 2 is ensured. The spring arms 11a, 11b have a lower height extension h3 than the mass electrodes 10a, 10b with a height extension h4, wherein the height extensions h3, h4 refer to an extension direction between the membranes 3, 4.

As can be further seen in FIG. 1, the sound measuring apparatus 7 has a stationary sound measuring electrode 16 and a signal electrode 17 mechanically coupled to the first membrane 3 as well as a signal electrode 17 coupled to the second membrane 4. The signal electrodes 17 together with the first membrane 3 and the second membrane 4 are movable relative to the stationary sound measuring electrode 16 and enable a pressure-signal-decoupled sound signal measurement. A plurality of spaced-apart coupling structures 24 serve to couple the membranes 3, 4 and the signal electrodes 17. The signal electrodes 17 have a lower total mass compared to the mass electrodes 10a, 10b in order to reduce acceleration-induced deflections in the sound measuring apparatus 7.

The first membrane 3 and the second membrane 4 are connected to one another by mechanical support columns 20 which extend through recesses not shown in detail in the stationary sound measuring electrode 16. By means of the support columns 20, the membranes 3, 4 can be prevented from collapsing into the cavity 6, and the measurement sensitivity of the membranes 3, 4 can be precisely adjusted. FIG. 1 also illustrates that the stationary acceleration measuring electrode 9 has a first height h1, and the stationary sound measuring electrode 16 has a second height h2, wherein the second height h2 is greater than the first height h1. The heights h1 and h2 refer to an extension direction of the acceleration measuring electrode 9 and the sound measuring electrode 16 between the first membrane 3 and the second membrane 4. Due to the different heights h1, h2, the measuring electrodes can be designed to be sufficiently stiff according to their different extensions extending in the direction of the end wall 5 without requiring excessive installation space, which can be used, for example, for an enlargement of the mass electrodes 10a, 10b. However, according to a different embodiment, it is also possible that the height h2 of the stationary sound measuring electrode 16 and the height h1 of the stationary acceleration measuring electrode 9 are the same, for example in embodiments in which the sound measuring electrode 16 and the acceleration measuring electrode 9 are designed as a common stationary counter electrode without mechanical separation.

Furthermore, it can be seen in FIG. 1 that the first membrane 3 and the second membrane 4, as well as the signal electrodes 17 coupled thereto, have potentials separate from one another so that a pressure measuring apparatus 18 is formed with the membranes 3, 4 and the signal electrodes 17. Accordingly, three different sensor variables can be covered with the described MEMS sensor component 1 without providing additional pressure measurement structures. To this end, the membranes 3, 4 have electrical insulation 15 to the signal electrodes 17.

FIG. 2 shows a top view of a section of the MEMS sensor component 1 enlarged compared to FIG. 1 according to the first embodiment, with the second membrane 4 hidden. FIG. 2 illustrates one possible design option for the spatial arrangement of the described components of the MEMS sensor component 1 in a circular cross section, wherein other geometric shapes and arrangements of the components relative to one another as well as other cross-sectional shapes are also possible. The support structure 2 shown in FIG. 3 forms a surrounding fastening surface 19. As indicated in FIG. 2, the stationary sound measuring electrode 16 and a plurality of stationary acceleration measuring electrodes 9, which are hidden in FIG. 2 by the mass electrodes 10 and spring arms 11, are fastened to different circumferential portions U1, U2 of the fastening surface 19. The acceleration measuring electrodes 9 are alternately connected to the fastening surface 19 with portions of the sound measuring electrode 16 clamped in an X-shaped manner. In the center of the arrangement, a ventilation opening 22 is formed which is limited by the surrounding end wall 5. In FIG. 2 it can further be seen that the acceleration measuring apparatuses 8 according to the shown exemplary embodiment are spaced apart from the sound measuring apparatus 7, in particular from the stationary sound measuring electrode 16, by an arc-shaped separating gap 21 so that there is a mechanical separation between the stationary sound measuring electrode 16 and the stationary acceleration measuring electrode 9. In the semicircular acceleration measurement ranges formed by the arc-shaped separating gap 21, two mass electrodes 10 arranged in a plane are fitted in a wing-like manner and connected to web-shaped spring arms 11. The signal electrodes 17 which are located below and above the sound measuring electrode 16 shown in FIG. 2 can be fitted circularly into a central region of the sensor structure between the acceleration measuring apparatuses 8.

FIG. 3 shows the described MEMS sensor component 1 according to the first embodiment with the support structure 2 in a cutaway side view. It can be seen that the support structure 2 can be formed by a substrate into which a recess has been introduced. The recess can form a pressure access 23 and be limited at least in portions by the aforementioned fastening surface 19, to which the first membrane 3, the second membrane 4, the mass electrodes 10a, 10b, the stationary acceleration measuring electrode 9 and the stationary sound measuring electrode 16 are fastened.

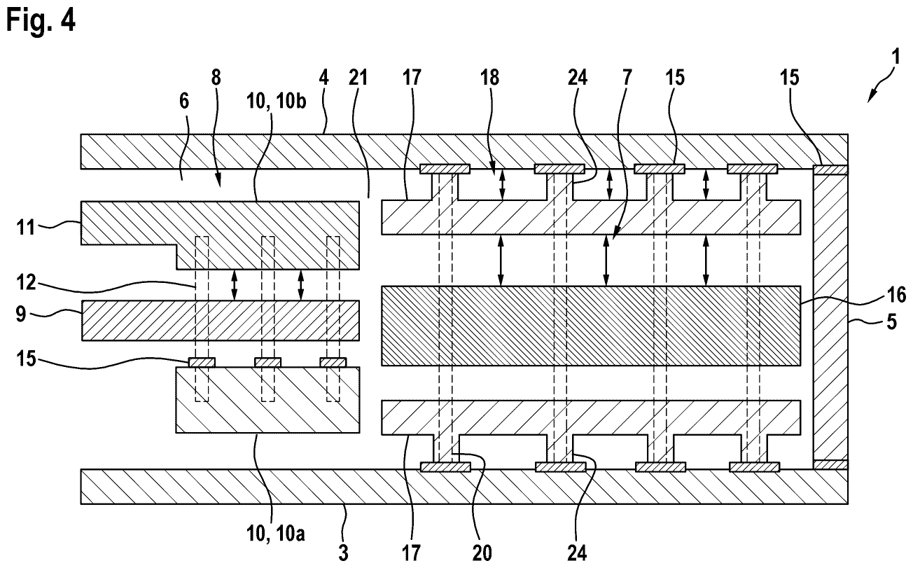

FIG. 4 shows a section of a MEMS sensor component 1 according to a second embodiment in a side sectional view. The shown MEMS sensor component 1 according to the second embodiment is fundamentally comparable in terms of its structure and operating principle to the MEMS sensor component 1 according to the first embodiment. However in contrast to this, in the second embodiment, the first mass electrode 10a and the second mass electrode 10b are connected to the support structure 2 via a common spring arm 11 projecting from the second mass electrode 10b, thereby improving the deflectability of the mass electrodes 10a, 10b.

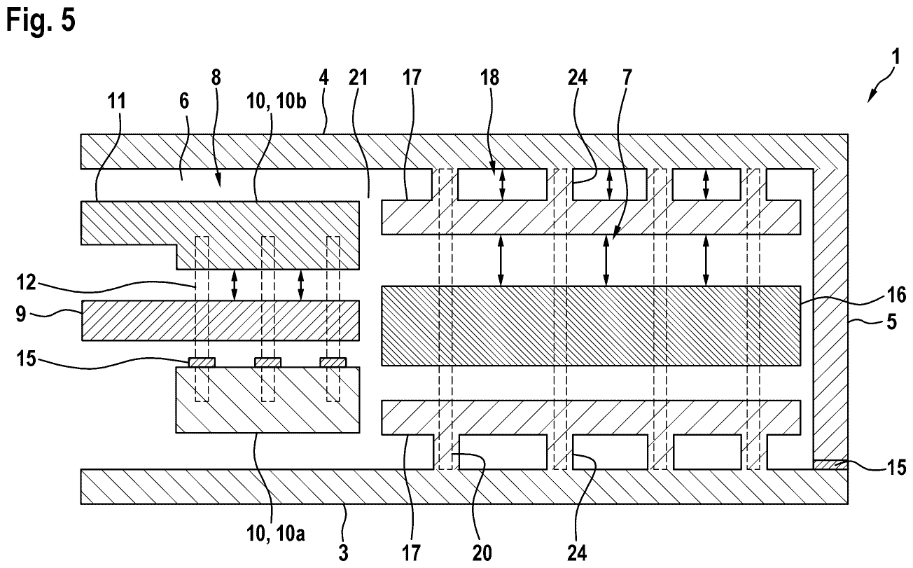

FIG. 5 shows a section of a MEMS sensor component 1 according to a third embodiment in a side sectional view. The shown MEMS sensor component 1 according to the third embodiment is fundamentally comparable in terms of its structure and operating principle to the MEMS sensor component 1 according to the second embodiment. In contrast to this, in the third embodiment, there are no electrical insulations 15 between the first membrane 3 and the signal electrode 17 coupled thereto, nor between the second membrane 4 and the signal electrode 17 coupled thereto so that in the MEMS sensor component 1 according to the third embodiment no pressure measuring apparatus 18 is implemented. This allows a simplified combination sensor with a sound measuring apparatus 7 and an acceleration measuring apparatus 8 to be created, which can be provided with reduced manufacturing effort and a simplified control and evaluation circuit.

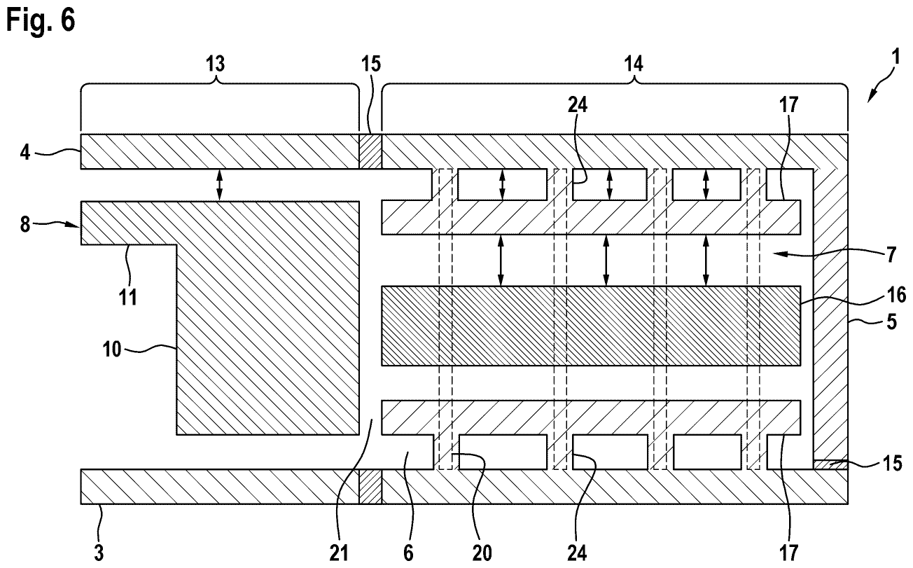

FIG. 6 shows a section of a MEMS sensor component 1 according to a fourth embodiment in a side sectional view. The shown MEMS sensor component 1 according to the fourth embodiment is fundamentally comparable in terms of its structure and operating principle to the MEMS sensor component 1 according to the third embodiment. However in contrast to this, the fourth embodiment provides that the first membrane 3 and the second membrane 4 each have an acceleration measuring portion 13 and a sound measuring portion 14 electrically insulated therefrom. A movable mass electrode 10 is arranged between the acceleration measuring portions 13 of the first membrane 3 and the second membrane 4. Electrical insulation 15 is provided between the acceleration measuring portions 13 and the sound measuring portions 14. The acceleration measuring portions 13 can form quasi-stationary counter electrodes to the mass electrode 10. This makes a stationary acceleration measuring electrode 9 unnecessary so that the mass electrode 10 can be designed larger.

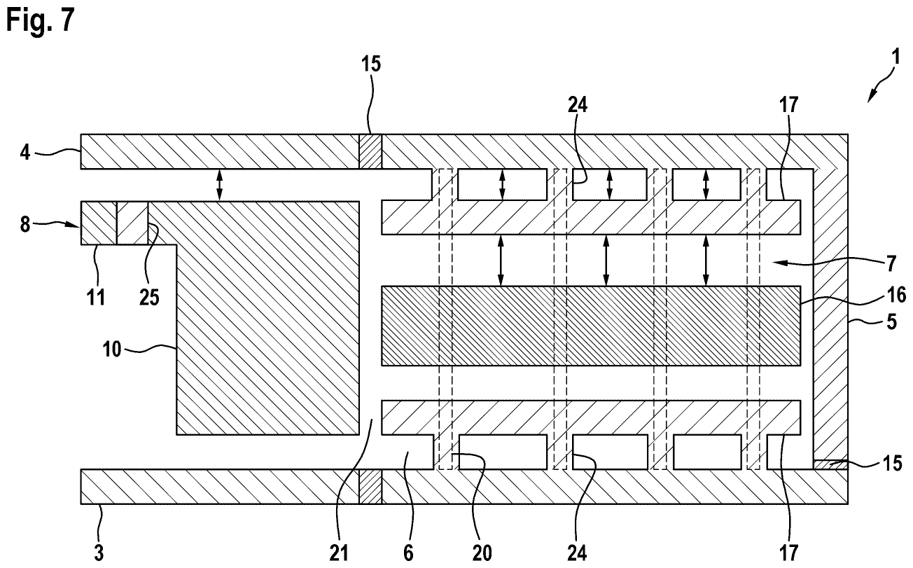

FIG. 7 shows a section of a MEMS sensor component 1 according to a fifth embodiment in a side sectional view. The shown MEMS sensor component 1 according to the fifth embodiment is basically comparable in terms of its structure and operating principle to the MEMS sensor component 1 according to the fourth embodiment. However in contrast to this, the fifth embodiment provides that the acceleration measuring apparatus 8 is designed as a piezoelectric acceleration measuring apparatus 8. For this purpose, a piezoelectric element 25 is arranged in the spring arm 11 whereby the mass electrode 10 is fastened to the support structure 2, and a mechanical stress effect in the spring arm 11 can thereby be converted into an electrical signal when the mass electrode 10 is deflected. This also makes a stationary acceleration measuring electrode 9 unnecessary so that the mass electrode 10 can be designed larger, as can be seen in FIG. 7. In principle, this embodiment can also be combined with the features of the fourth embodiment so that in addition to the piezoelectric deflection detection, a capacitive measurement of the deflection of the mass electrode 10 is possible via an acceleration measuring portion 13 of the first membrane 3 and/or the second membrane 4 as a counter electrode.

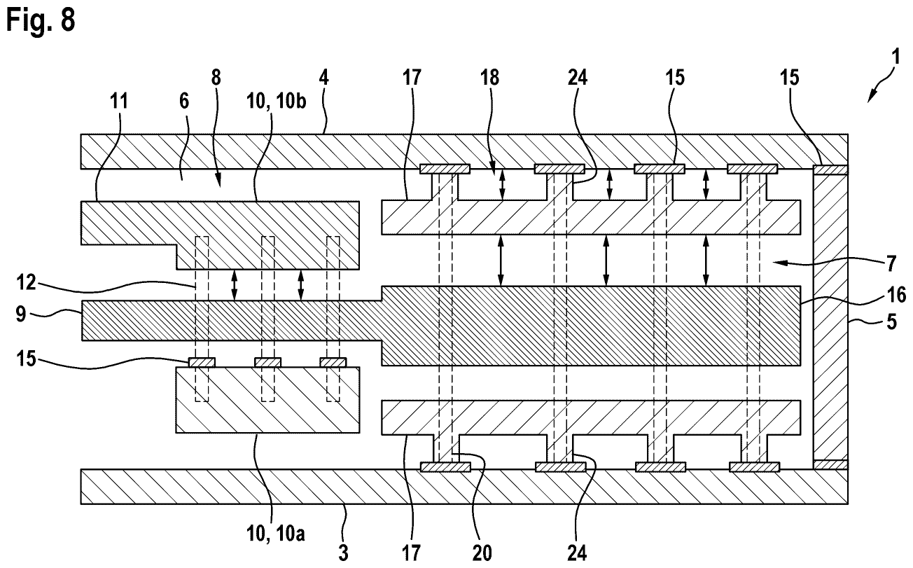

FIG. 8 shows a section of a MEMS sensor component 1 according to a sixth embodiment in a side sectional view. The shown MEMS sensor component 1 according to the sixth embodiment is basically comparable in terms of its structure and operating principle to the MEMS sensor component 1 according to the second embodiment. However in contrast to this, the sixth embodiment provides that the stationary acceleration measuring electrode 9 transitions directly into the stationary sound measuring electrode 16 so that these form a common counter electrode with increased stability for the mass electrodes 10 and the signal electrodes 17. This allows an easily designed and produced as well as robust MEMS sensor component 1 to be provided. The height extension of the stationary acceleration measuring electrode 9 and the stationary sound measuring electrode 16 can optionally be adjusted to one another.

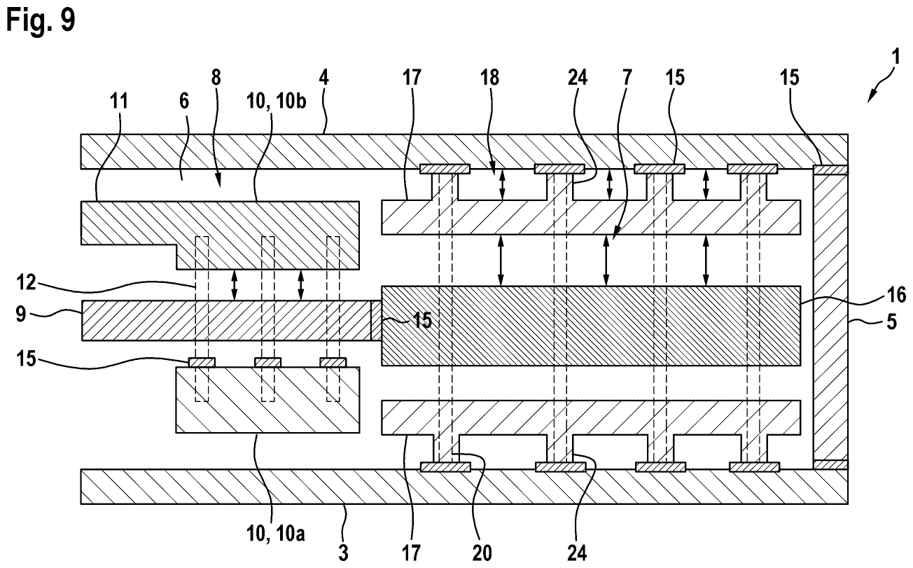

FIG. 9 shows a section of a MEMS sensor component 1 according to a seventh embodiment in a side sectional view. The shown MEMS sensor component 1 according to the seventh embodiment is basically comparable in terms of its structure and operating principle to the MEMS sensor component 1 according to the sixth embodiment. However in contrast to this, the seventh embodiment provides that an electrical insulation 15, for example made of a silicon nitride or silicon oxide, is arranged between the stationary acceleration measuring electrode 9 and the stationary sound measuring electrode 16. This allows for a common counter electrode with high stability and simultaneously reduced parasitic capacitances to be created.

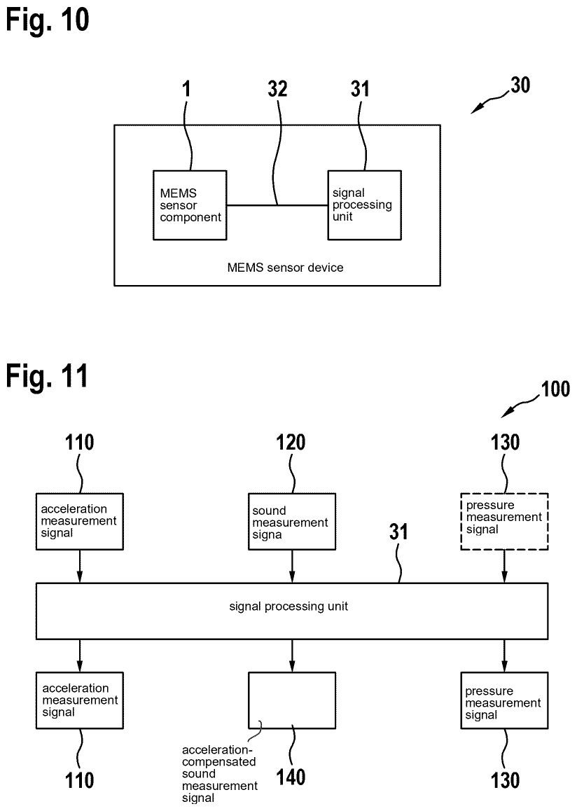

A schematic diagram of a MEMS sensor device 30 with a MEMS sensor component 1 can be seen in FIG. 10, wherein the MEMS sensor component 1 is designed according to one of the above described features. The MEMS sensor component 1 is connected to a signal processing unit 31 of the MEMS sensor device 30 via a signal connection 32, for example a wire bond connection. The signal processing unit 31 can, for example, be designed as an ASIC. The MEMS sensor device 30 is compact and can be produced inexpensively.

FIG. 11 illustrates in a schematic diagram an exemplary embodiment of a method 100 for operating a MEMS sensor device 30 which can be designed as described above. In so doing, an acceleration measurement signal 110 from the acceleration measuring apparatus 8, a sound measurement signal 120 from the sound measuring apparatus 7 and an optional pressure measurement signal 130 from the pressure measuring apparatus 18 are supplied to the signal processing unit 31 of the MEMS sensor device 30. The signal processing unit 31 can, for example, provide the acceleration measurement signal 110, an acceleration-compensated sound measurement signal 140 and the pressure measurement signal 130 based on the supplied measurement signals, or process them internally within the control system. With the provided or processed measurement signals, differentiated and complex evaluations can be performed, for example to enable very accurate sound measurement signals, structure-borne sound measurements or function controls on the MEMS sensor device 30.

What is claimed is:

1. A MEMS sensor component, comprising:
a support structure;
a first membrane and a second membrane which are anchored to the support structure and connected to one another by an end wall;
a cavity which is bordered by the support structure, the first membrane, the second membrane, and the end wall;
a sound measuring apparatus arranged in the cavity and configured to detect a sound signal acting on the first membrane and/or the second membrane; and
an acceleration measuring apparatus arranged in the cavity and configured to detect an acceleration force acting on the MEMS sensor component.

2. The MEMS sensor component according to claim 1, wherein the sound measuring apparatus includes a capacitive sound measuring apparatus and/or the acceleration measuring apparatus includes a capacitive acceleration measuring apparatus or a piezoelectric acceleration measuring apparatus.

3. The MEMS sensor component according to claim 1, wherein, starting from a fastening of the acceleration measuring apparatus to the support structure viewed in a direction of the end wall, the acceleration measuring apparatus and the sound measuring apparatus follow one another.

4. The MEMS sensor component according to claim 1, wherein the acceleration measuring apparatus includes a stationary acceleration measuring electrode and a mass electrode movable relative to the stationary acceleration measuring electrode.

5. The MEMS sensor component according to claim 4, wherein the mass electrode is fastened to the support structure by a spring arm arranged between the stationary acceleration measuring electrode and the first membrane or the second membrane.

6. The MEMS sensor component according to claim 4, wherein the acceleration measuring apparatus includes a first mass electrode arranged between the stationary acceleration measuring electrode and the first membrane, and a second mass electrode arranged between the stationary acceleration measuring electrode and the second membrane.

7. The MEMS sensor component according to claim 6, wherein the first mass electrode and the second mass electrode are mechanically connected to one another by a connecting element, wherein the connecting element extends through a recess in the stationary acceleration measuring electrode.

8. The MEMS sensor component according to claim 6, wherein the first mass electrode is fastened to the support structure by a first spring arm arranged between the stationary acceleration measuring electrode and the first membrane, and wherein the second mass electrode is fastened to the support structure by a second spring arm arranged between the stationary acceleration measuring electrode and the second membrane.

9. The MEMS sensor component according to claim 1, wherein the first membrane and/or the second membrane includes an acceleration measuring portion, and a sound measuring portion electrically insulated from the acceleration measuring portion, and wherein the acceleration measuring apparatus includes a mass electrode movable relative to the acceleration measuring portion.

10. The MEMS sensor component according to claim 1, wherein the sound measuring apparatus includes a stationary sound measuring electrode, and a signal electrode mechanically coupled to the first membrane or the second membrane, the signal electrode being movable relative to the stationary sound measuring electrode.

11. The MEMS sensor component according to claim 10, wherein the stationary sound measuring electrode and the stationary acceleration measuring electrode are mechanically separated from one another and/or electrically separated from one another.

12. The MEMS sensor component according to claim 10, wherein the stationary sound measuring electrode has a greater height extension between the first membrane and the second membrane (4) than the stationary acceleration measuring electrode (9).

13. The MEMS sensor component according to claim 11, wherein the first membrane or the second membrane, and the signal electrode coupled to the first membrane or the second membrane, have separate electrical potentials from one another and form a pressure measuring apparatus.

14. The MEMS sensor component according to claim 10, wherein the support structure forms a surrounding fastening surface, and wherein the stationary sound measuring electrode and the stationary acceleration measuring electrode are fastened to different circumferential portions of the fastening surface.

15. The MEMS sensor component according to claim 10, wherein the first membrane and the second membrane are connected to one another by a mechanical support column that extends through a recess in the stationary sound measuring electrode.

16. A MEMS sensor device, comprising:
a MEMS sensor component; and
a signal processing unit configured to at least one of receive, apply, or process signals of the MEMS sensor component;
wherein the MEMS sensor component includes:
a support structure.
a first membrane and a second membrane which are anchored to the support structure and connected to one another by an end wall.
a cavity which is bordered by the support structure, the first membrane, the second membrane, and the end wall.
a sound measuring apparatus arranged in the cavity and configured to detect a sound signal acting on the first membrane and/or the second membrane. and
an acceleration measuring apparatus arranged in the cavity and configured to detect an acceleration force acting on the MEMS sensor component.

17. A method for operating a MEMS sensor device, the MEMS sensor device including:
a MEMS sensor component, and
a signal processing unit configured to at least one of receive, apply, or process signals of the MEMS sensor component,
wherein the MEMS sensor component includes:
a support structure,
a first membrane and a second membrane which are anchored to the support structure and connected to one another by an end wall,
a cavity which is bordered by the support structure, the first membrane, the second membrane, and the end wall,
a sound measuring apparatus arranged in the cavity and configured to detect a sound signal acting on the first membrane and/or the second membrane, and
an acceleration measuring apparatus arranged in the cavity and configured to detect an acceleration force acting on the MEMS sensor component,
the method comprising at least one of the following steps:
providing or processing, by the signal processing unit, an acceleration-compensated sound measurement signal from the sound measuring apparatus, based on an acceleration measurement signal from the acceleration measuring apparatus, or
providing or processing, by the signal processing unit, at least one of: (i) an acceleration measurement signal from the acceleration measuring apparatus, (ii) a sound measurement signal from the sound measuring apparatus, or (iii) a pressure measurement signal from the pressure measuring apparatus, independently of one another.
